(19) United States
(12) Patent Application Publication
(10) Pub. No.: US 2010/0127259 A1
(43) Pub. Date: May 27, 2010

(54) SEMICONDUCTOR DEVICE

(75) Inventor: Tetsuro Nozu, Tokyo (JP)

Correspondence Address: PATTERSON & SHERIDAN, L.L.P., 3040 POST OAK BOULEVARD, SUITE 1500, HOUSTON, TX, 77056, US

(73) Assignee: KABUSHIKI KAISHA TOSHIBA, Tokyo (JP)

(21) Appl. No.: 12/558,474

(22) Filed: Sep. 11, 2009

(30) Foreign Application Priority Data
Nov. 26, 2008 (JP) 2008-300919

(51) Int. Cl. H01L 27/06; H01L 29/04

(52) U.S. Cl. 257/49; 257/355; 361/56; 257/E27.016; 257/E29.003

(57) ABSTRACT

A semiconductor device has a MOS transistor that has a gate connected to a first terminal, a source connected to a second terminal and a drain connected to a third terminal, a first polysilicon diode that has an anode connected to the first terminal, a first single-crystalline silicon diode that is connected to a cathode of the first polysilicon diode at a cathode thereof and to the second terminal at an anode thereof, has a reverse breakdown voltage lower than a reverse breakdown voltage of the first polysilicon diode, a second polysilicon diode that has a cathode connected to the first terminal and a second single-crystalline silicon diode that is connected to an anode of the second polysilicon diode at an anode thereof and to the third terminal at a cathode thereof, has a reverse breakdown voltage lower than a reverse breakdown voltage of the second polysilicon.

### CROSS-REFERENCE TO RELATED APPLICATION

This application is based upon and claims the benefit of priority from the prior Japanese Patent Application No. 2008-300919, filed on Nov. 26, 2008, the entire contents of which are incorporated herein by reference.

### BACKGROUND OF THE INVENTION

1. Field of the Invention

The present invention relates to a semiconductor device with a MOS transistor.

2. Background Art

With the recent trend toward higher speed and capacity in the information technology, technical requirements on size and frequency of electronic devices are becoming stricter. Accordingly, demands for improvement of the electrostatic destruction resistance of the electronic devices are also growing.

For example, MOS transistors are widely used in compact high-speed switching devices, voltage converter circuits and the like in portable apparatuses. However, the MOS transistors have a problem that the electrostatic destruction resistance (ESD resistance) can be lowered as a result of miniaturization of the device or reduction in thickness of the gate oxide film. As a solution to the problem, there is proposed a structure that has higher ESD resistance due to a protective element (protective diode) inserted between the gate electrode and the source electrode of the MOS transistor (see Japanese Patent Laid-Open No. 11-284175, for example).

In order to reduce the device size, the protective diode is often formed on the silicon substrate at the same time as the MOS structure.

In particular, a protective element made from a polysilicon thin film provides high flexibility for the device manufacturing process and thus is widely used.

However, in general, a PN diode made from a polysilicon thin film has lower breakdown voltage or breakdown current than a PN diode made from single-crystalline silicon. This is probably due to the difference in crystallinity.

In addition, a detailed investigation of destruction of two protective diodes reverse-connected in series with each other has showed that the protective diode operating in the reverse direction is more likely to be destructed. More specifically, the breakdown voltage and thus the power consumption are higher in the reverse operation than in the forward operation. As a result, the reverse operation involves a greater instantaneous heat generation and thus is more likely to cause destruction of the protective diode.

In particular, in the human body model (HBM) in which the element is destructed in the constant current operation mode, destruction of the protective diode is considerable. The protective diode structure made from a polysilicon thin film has lower destruction resistance than the diode made from single-crystalline silicon. Therefore, in order to achieve a sufficient resistance, the footprint of the protective element has to be increased.

As described above, the diode made from a polysilicon thin film and used as an ESD protective element has a problem that the ESD resistance is lower than the diode made from single-crystalline silicon.

### SUMMARY OF THE INVENTION

According to one aspect of the present invention, there is provided: a semiconductor device, comprising:

a MOS transistor that is formed on a semiconductor substrate, and has a gate connected to a first terminal, a source connected to a second terminal and a drain connected to a third terminal;

a first polysilicon diode that is formed on the semiconductor substrate with an insulating film interposed therebetween, has an anode connected to the first terminal, and is made of polysilicon;

a first single-crystalline silicon diode that has a cathode connected to a cathode of the first polysilicon diode and an anode connected to the second terminal, has a reverse breakdown voltage lower than a reverse breakdown voltage of the first polysilicon diode, and is made of single-crystalline silicon;

a second polysilicon diode that is formed on the semiconductor substrate with an insulating film interposed therebetween, has a cathode connected to the first terminal, and is made of polysilicon; and

a second single-crystalline silicon diode that has an anode connected to an anode of the second polysilicon diode and a cathode connected to the third terminal, has a reverse breakdown voltage lower than a reverse breakdown voltage of the second polysilicon, and is made of single-crystalline silicon.

According to another aspect of the present invention, there is provided: a semiconductor device, comprising:

a MOS transistor that is formed on a semiconductor substrate, and has a gate connected to a first terminal, a source connected to a second terminal and a drain connected to a third terminal;

a first diode circuit that is formed on the semiconductor substrate with an insulating film interposed therebetween, includes a plurality of polysilicon diodes made of polysilicon connected in series with each other, and is connected to the first terminal at an anode side thereof;

a first single-crystalline silicon diode that is connected to a cathode side of the first diode circuit at a cathode thereof and to the second terminal at an anode thereof, has a reverse breakdown voltage lower than a sum of reverse breakdown voltages of the plurality of polysilicon diodes of the first diode circuit, and is made of single-crystalline silicon;

a second diode circuit that is formed on the semiconductor substrate with an insulating film interposed therebetween, includes a plurality of polysilicon diodes made of polysilicon connected in series with each other, and is connected to the first terminal at a cathode side thereof; and

a second single-crystalline silicon diode that is connected to an anode side of the second diode circuit at an anode thereof and to the third terminal at a cathode thereof, has a reverse breakdown voltage lower than a sum of reverse breakdown voltages of the plurality of polysilicon diodes of the second diode circuit connected in series with each other, and is made of single-crystalline silicon.

According to still another aspect of the present invention, there is provided: a semiconductor device, comprising:

a MOS transistor that is formed on a semiconductor substrate and has a gate connected to a first terminal, a source connected to a second terminal and a drain connected to a third terminal;

a first polysilicon diode that is formed on the semiconductor substrate with an insulating film interposed therebetween, has an anode connected to the first terminal, and is made of polysilicon;

a second polysilicon diode that is formed on the semiconductor substrate with an insulating film interposed therebetween, has a cathode connected to a cathode of the first polysilicon diode and an anode connected to the second or third terminal, and is made of polysilicon;

a third polysilicon diode that is formed on the semiconductor substrate with an insulating film interposed therebetween, has a cathode connected to the first terminal, and is made of polysilicon;

a fourth polysilicon diode that is formed on the semiconductor substrate with an insulating film interposed therebetween, has an anode side connected to an anode of the third polysilicon diode and a cathode connected to the anode of the second polysilicon diode, and is made of polysilicon; and

a single-crystalline silicon diode that has a cathode connected to the cathode of the first polysilicon diode and an anode connected to the anode of the third polysilicon diode, has a reverse breakdown voltage lower than a reverse breakdown voltage of the first polysilicon diode, a reverse breakdown voltage of the second polysilicon diode, a reverse breakdown voltage of the third polysilicon diode and a reverse breakdown voltage of the fourth polysilicon diode, and is made of single-crystalline silicon.

According to still another aspect of the present invention, there is provided: a semiconductor device, comprising:

a MOS transistor that is formed on a semiconductor substrate and has a gate connected to a first terminal, a source connected to a second terminal and a drain connected to a third terminal;

a first diode circuit that is formed on the semiconductor substrate with an insulating film interposed therebetween, includes a plurality of polysilicon diodes made of polysilicon connected in series with each other and is connected to the first terminal at an anode side thereof;

a second diode circuit that is formed on the semiconductor substrate with an insulating film interposed therebetween, includes a plurality of polysilicon diodes made of polysilicon connected in series with each other and is connected to a cathode side of the first diode circuit at a cathode side thereof and to the second or third terminal at an anode side thereof;

a third diode circuit that is formed on the semiconductor substrate with an insulating film interposed therebetween, includes a plurality of polysilicon diodes made of polysilicon connected in series with each other and is connected to the first terminal at a cathode side thereof;

a fourth diode circuit that is formed on the semiconductor substrate with an insulating film interposed therebetween, includes a plurality of polysilicon diodes made of polysilicon connected in series with each other and is connected to an anode side of the third diode circuit at an anode side thereof and to the anode side of the second diode circuit at a cathode side thereof; and

a single-crystalline silicon diode that is connected to the cathode side of the first diode circuit at a cathode thereof and to the anode side of the third diode circuit at an anode thereof, has a reverse breakdown voltage lower than a sum of reverse breakdown voltages of the plurality of polysilicon diodes of the first diode circuit, a sum of reverse breakdown voltages of the plurality of polysilicon diodes of the second diode circuit, a sum of reverse breakdown voltages of the plurality of polysilicon diodes of the third diode circuit and a sum of reverse breakdown voltages of the plurality of polysilicon diodes of the fourth diode circuit, and is made of single-crystalline silicon.

### BRIEF DESCRIPTION OF THE DRAWINGS

FIG. 1 is a circuit diagram showing an exemplary circuit configuration of a semiconductor device 100 according to an embodiment 1 of the present invention, which is an aspect of the present invention;

FIG. 2 is a cross-sectional view showing a configuration of the first diode circuit 116 formed on the semiconductor substrate of the semiconductor device 100 with an oxide film interposed therebetween;

FIG. 3 is a cross-sectional view showing a configuration of the first single-crystalline silicon diodes 18 and the second single-crystalline silicon diode 19 formed in the semiconductor substrate of the semiconductor device 100;

FIG. 4 is a cross-sectional view showing a configuration of the semiconductor device 100 including the diodes shown in FIGS. 2 and 3;

FIG. 5 is a plan view showing an exemplary layout of the protective diode structure of the semiconductor device 100;

FIG. 6 is a cross-sectional view of the semiconductor device 100 taken along the line A-A in FIG. 5;

FIG. 7 is a circuit diagram showing an exemplary circuit configuration of a semiconductor device 200 according to the embodiment 2 of the present invention, which is an aspect of the present invention;

FIG. 8 is a plan view showing an exemplary layout of a protective diode structure of the semiconductor device 200 shown in FIG. 7; and

FIG. 9 is a cross-sectional view of the semiconductor device 200 taken along the line B-B in FIG. 8.

### DETAILED DESCRIPTION

In the following, embodiments of the present invention will be described with reference to the drawings. The following description will be focused on a case where the MOS transistor is an n-MOS transistor. However, the present invention can be equally applied to a case where the MOS transistor is a p-MOS transistor by changing the polarity of the circuit.

### Embodiment 1

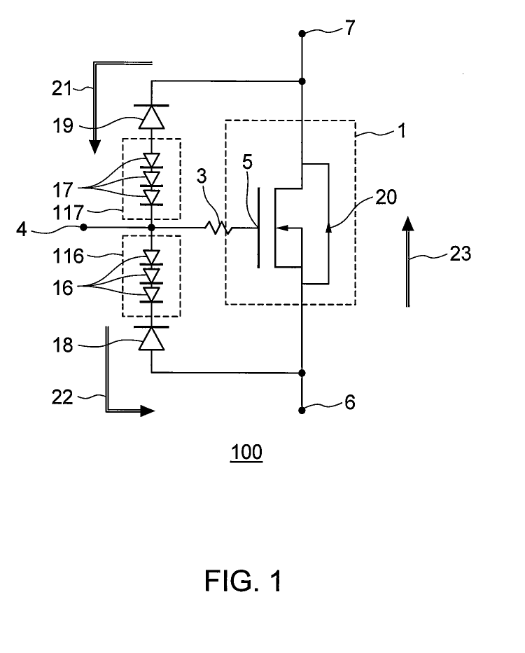

FIG. 1 is a circuit diagram showing an exemplary circuit configuration of a semiconductor device 100 according to an embodiment 1 of the present invention, which is an aspect of the present invention.

As shown in FIG. 1, the semiconductor device 100 has a MOS transistor 1, a resistor 3, a first terminal (gate terminal) 4, a second terminal (source terminal) 6, a third terminal (drain terminal) 7, a first diode circuit 116, a second diode circuit 117, a first single-crystalline silicon diode 18 and a second single-crystalline silicon diode 19.

The MOS transistor 1 is formed on a semiconductor substrate (single-crystalline silicon substrate). The MOS transistor 1 has a gate connected to the first terminal 4, a source connected to the second terminal 6 and a drain connected to the third terminal 7.

The resistor 3 is connected between a gate electrode 5 of the MOS transistor 1 and the first terminal 4. This helps improve the ESD resistance of the MOS transistor 1.

As described earlier, the MOS transistor 1 is an n-MOS transistor in this specification. The MOS transistor 1 has a parasitic diode 20 between the source and the drain.

The first diode circuit 116 is formed on the semiconductor substrate with an insulating film interposed therebetween. The first diode circuit 116 is composed of a plurality of first polysilicon diodes 16 made of polysilicon connected in series with each other. The first diode circuit 116 is connected to the first terminal 4 at the anode side of the first polysilicon diodes 16.

Alternatively, the first diode circuit 116 may be composed of a single first polysilicon diode 16. In that case, the first polysilicon diode 16 is formed on the semiconductor substrate with an insulating film interposed therebetween and is made of polysilicon. The first polysilicon diode 16 is connected to the first terminal 4 at the anode thereof.

The first single-crystalline silicon diode 18 is connected to the cathode side of the first polysilicon diodes 16 of the first diode circuit 116 at the cathode thereof and to the second terminal 6 at the anode thereof. The first single-crystalline silicon diode 18 has a reverse breakdown voltage lower than the sum of the reverse breakdown voltages of the plurality of first polysilicon diodes 16 of the first diode circuit 116. The first single-crystalline silicon diode 18 is made of single-crystalline silicon.

In the case where the first diode circuit 116 is composed of a single first polysilicon diode 16, the first single-crystalline silicon diode 18 is connected to the cathode of the first polysilicon diode 16 at the cathode thereof and to the second terminal 6 at the anode thereof. In that case, the first single-crystalline silicon diode 18 has a reverse breakdown voltage lower than the reverse breakdown voltage of the single first polysilicon diode 16.

The second diode circuit 117 is formed on the semiconductor substrate with an insulating film interposed therebetween. The second diode circuit 117 is composed of a plurality of second polysilicon diodes 17 made of polysilicon connected in series with each other. The second diode circuit 117 is connected to the first terminal 4 at the cathode side of the second polysilicon diodes 17.

Alternatively, the second diode circuit 117 may be composed of a single second polysilicon diode 17. In that case, the second polysilicon diode 17 is formed on the semiconductor substrate with an insulating film interposed therebetween and is made of polysilicon. The second polysilicon diode 17 is connected to the first terminal 4 at the cathode thereof.

The second single-crystalline silicon diode 19 is connected to the anode side of the second diode circuit 117 at the anode thereof and to the third terminal 7 at the cathode thereof. The second single-crystalline silicon diode 19 has a reverse breakdown voltage lower than the sum of the reverse breakdown voltages of the plurality of second polysilicon diodes of the second diode circuit 117 connected in series with each other and is made of single-crystalline silicon.

In the case where the second diode circuit 117 is composed of a single second polysilicon diode 17, the second single-crystalline silicon diode 19 is connected to the anode of the second polysilicon diode 17 at the anode thereof and to the third terminal 7 at the cathode thereof. In that case, the second single-crystalline silicon diode 19 has a reverse breakdown voltage lower than the reverse breakdown voltage of the single second polysilicon diode 17.

Next, a configuration of a protective element portion formed on the same semiconductor substrate (single-crystalline silicon substrate) as the MOS transistor 1 of the semiconductor device 100 will be described. First, individual components of the protective element portion will be described, and then, an assembly of the components will be described.

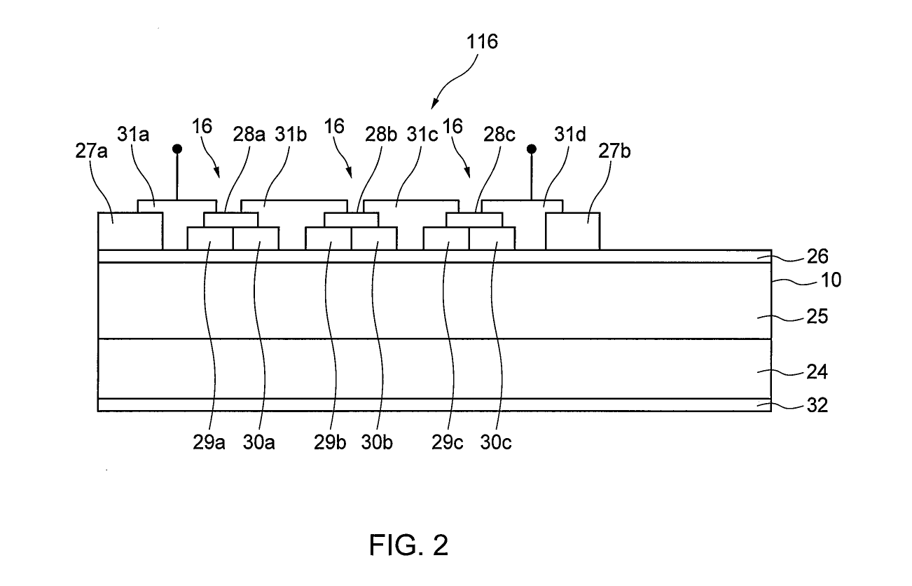

FIG. 2 is a cross-sectional view showing a configuration of the first diode circuit 116 formed on the semiconductor substrate of the semiconductor device 100 with an oxide film interposed therebetween. The second diode circuit 117 has the same configuration as that shown in FIG. 2 except that the polarity of the portion of the PN-junction diodes is reversed.

As shown in FIG. 2, the semiconductor substrate 10 includes an N-type silicon substrate 24 and an N-type epitaxial layer 25 formed on the N-type silicon substrate 24. A back-side electrode 32 is formed on a back surface of the semiconductor substrate 10. An insulating film 26 is selectively formed on the semiconductor substrate 10.

The first diode circuit 116 is formed on the semiconductor substrate 10 with the insulating film 26 interposed therebetween. Al electrodes 31a and 31d are formed on the opposite ends of the first diode circuit 116.

The first polysilicon diodes (PN-junction diodes) 16 connected in series with each other are composed of P-type polysilicon layers 30a, 30b and 30c formed on the insulating film 26 and N-type polysilicon layers 29a, 29b and 29c formed on the insulating film 26.

In addition, metal parts (Al electrodes) 31b and 31c are connected between the first polysilicon diodes connected in series with each other.

If a semiconductor layer is connected between the first polysilicon diodes 16, for example, an NPN structure is formed. In that case, the snap-back effect can occur. More specifically, after the first polysilicon diodes 16 yield to the reverse breakdown voltage, a current becomes able to flow at a lower voltage. In that case, a desired sufficiently high withstand voltage cannot be assured.

However, according to the embodiment 1, the three pairs of first polysilicon diodes 16 are electrically connected to each other by the metal electrodes. Therefore, no NPN structure is formed, and therefore, the snap-back effect can be suppressed. As a result, a desired sufficiently high withstand voltage can be assured.

The same effect can be achieved even if, as an alternative to the metal parts, semiconductor parts having a minority carrier recombination rate approximately equal to that of the metal parts are connected between the polysilicon diodes connected in series with each other.

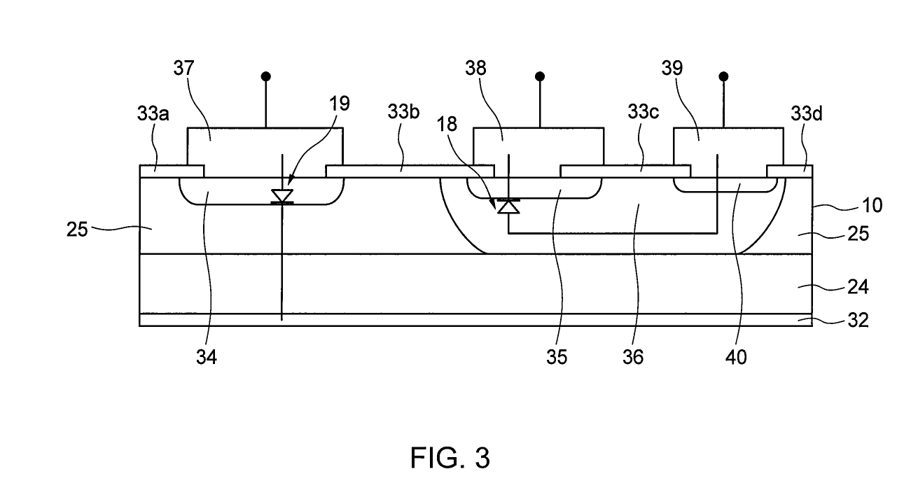

FIG. 3 is a cross-sectional view showing a configuration of the first single-crystalline silicon diodes 18 and the second single-crystalline silicon diode 19 formed in the semiconductor substrate of the semiconductor device 100. In this embodiment, the N-type silicon substrate 24 is used as the drain of the MOS transistor, and therefore, the back-side electrode 32 constitutes the third terminal (drain electrode) 7.

As shown in FIG. 3, the first single-crystalline silicon diode (PN-junction diode) 18 is composed of a P-type diffusion well region 36 formed in the N-type epitaxial layer 25 and an N-type diffusion region 35 formed in the P-type diffusion well region 36.

The cathode of the first single-crystalline silicon diode 18 is connected to an Al electrode 38 formed on the N-type diffusion region 35. The anode of the first single-crystalline silicon diode 18 is connected to an Al electrode 39 via a P+ diffusion region 40. The presence of the P+ diffusion region 40 allows formation of an ohmic contact in the P-type diffusion well region 36.

The second single-crystalline silicon diode (PN-junction diode) 19 is composed of the N-type epitaxial layer 25 and a P-type diffusion region 34 formed in the N-type epitaxial layer 25.

The cathode of the second single-crystalline silicon diode 19 is connected to the back-side electrode 32 (third terminal 7) via the N-type silicon substrate 24. The anode of the second single-crystalline silicon diode 19 is connected to an Al electrode 37 formed on the P-type diffusion region 34.

As can be seen from the above description, the first single-crystalline silicon diode 18 and the second single-crystalline silicon diode 19 are formed in the N-type epitaxial layer 25, which is a single-crystalline silicon layer in the semiconductor substrate 10.

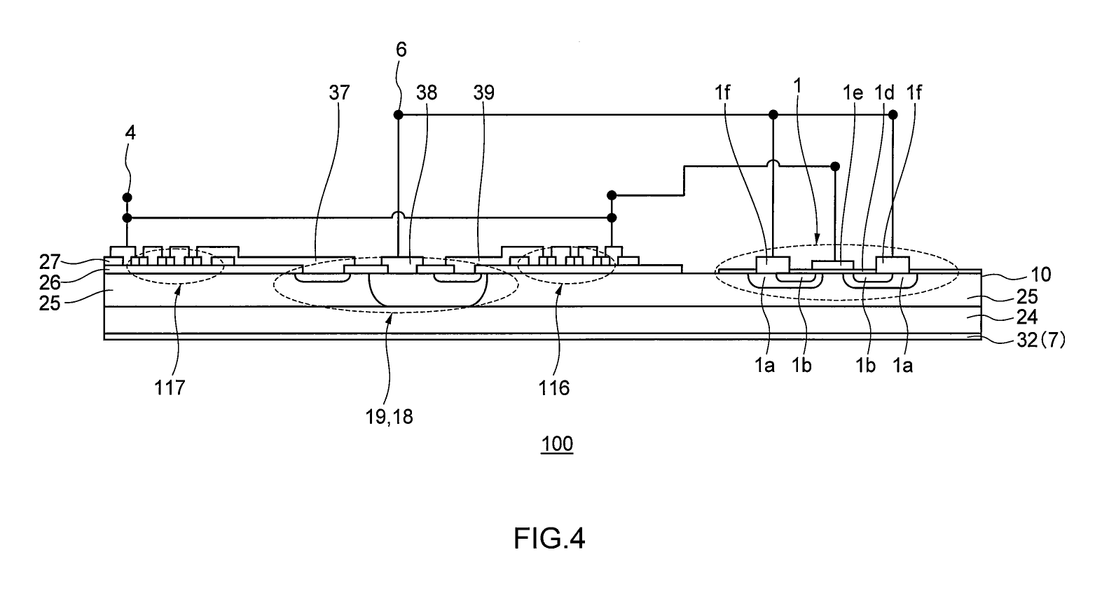

FIG. 4 is a cross-sectional view showing a configuration of the semiconductor device 100 including the diodes shown in FIGS. 2 and 3.

As shown in FIG. 4, the MOS transistor 1 is formed on the semiconductor substrate 10. The MOS transistor 1 has a P-type base region 1a formed in the N-type epitaxial layer 25, an N-type source region 1b formed in the P-type base region 1a, an N-type drain region is formed in the N-type epitaxial layer 25, a gate electrode 1e formed on the N-type epitaxial layer 25 with a gate insulating film 1d interposed therebetween, a source electrode if formed on the N-type source region 1b, and the back-side electrode 32, which constitutes the drain electrode.

Furthermore, as shown in FIG. 4, the protective element shown in FIG. 1 is formed by two pairs of reverse-connected diodes, one of the paired diodes being made of polysilicon and the other being made of single-crystalline silicon, inserted between the gate electrode and the drain electrode and between the gate electrode and the source electrode, respectively.

Next, an exemplary layout intended to reduce the size of the protective diode structure of the semiconductor device 100 will be described.

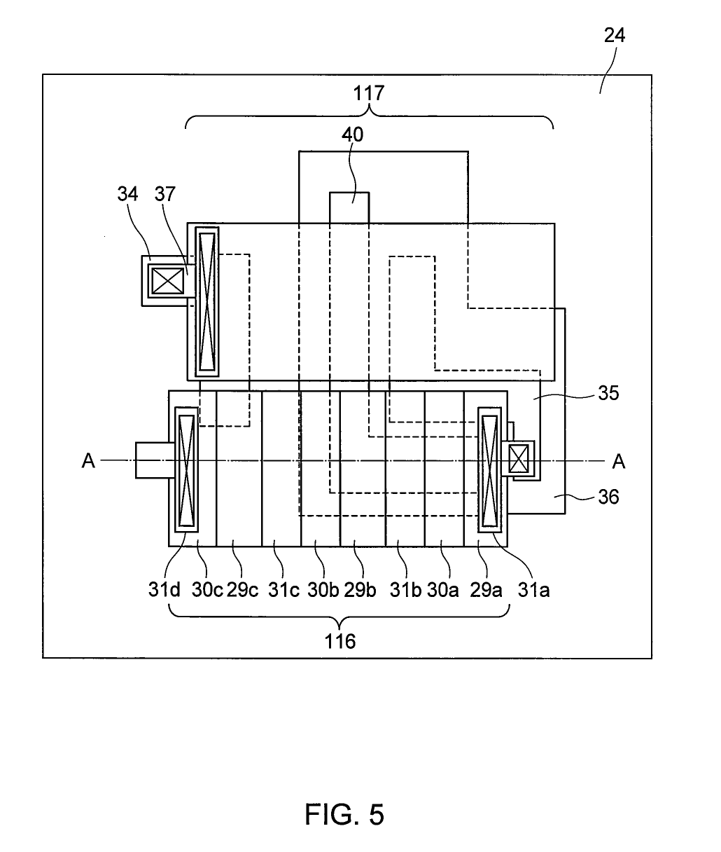

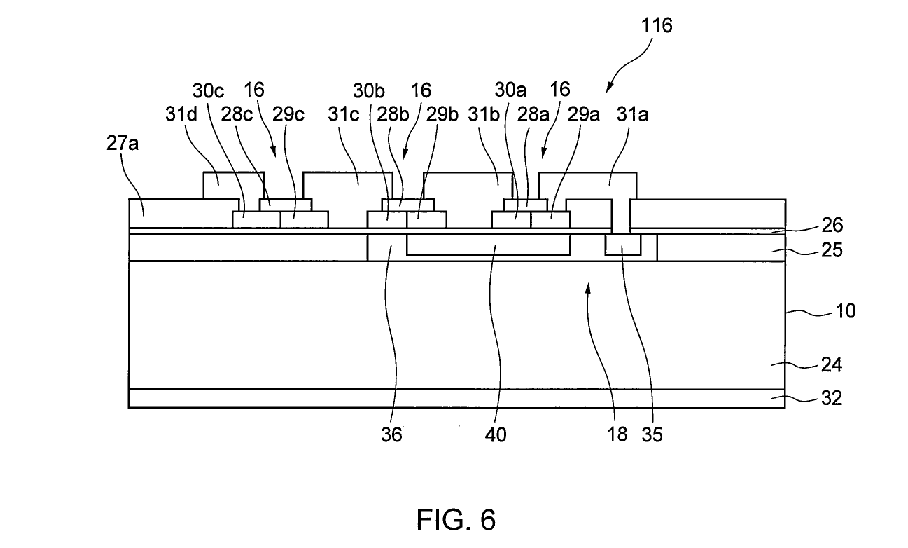

FIG. 5 is a plan view showing an exemplary layout of the protective diode structure of the semiconductor device 100. FIG. 6 is a cross-sectional view of the semiconductor device 100 taken along the line A-A in FIG. 5. For the sake of clarity, these drawings show only essential parts. FIG. 6 shows a cross section of the first diode circuit 116 and the vicinity thereof.

As shown in FIGS. 5 and 6, the semiconductor substrate 10 includes the N-type silicon substrate 24 and the N-type epitaxial layer 25 formed on the N-type silicon substrate 24. The back-side electrode 32 is formed on the back surface of the semiconductor substrate 10. The insulating film 26 is selectively formed on the semiconductor substrate 10.

The first diode circuit 116 is formed on the first single-crystalline silicon diode 18 with the insulating film 26 interposed therebetween.

As shown in FIGS. 5 and 6, the first diode circuit 116 is formed on the semiconductor substrate 10 with the insulating film 26 interposed therebetween. The electrodes 31a and 31d are formed on the opposite ends of the first diode circuit 116.

The first polysilicon diodes (PN-junction diodes) 16 connected in series with each other are composed of the P-type polysilicon layers 30a, 30b and 30c formed on the insulating film 26 and the N-type polysilicon layers 29a, 29b and 29c formed on the insulating film 26.

In addition, the metal parts (Al electrodes) 31b and 31c are connected between the first polysilicon diodes connected in series with each other.

Similarly, the second diode circuit 117 is formed on the second single-crystalline silicon diode 19 with the insulating film 26 interposed therebetween. The second diode circuit 117 has the same configuration as the first diode circuit 116 except that the polarity of the portion of the PN-junction diodes is reversed.

As shown in FIG. 6, the first single-crystalline silicon diode (PN-junction diode) 18 is composed of the P-type diffusion well region 36 formed in the N-type epitaxial layer 25 and the N-type diffusion region 35 formed in the P-type diffusion well region 36.

The cathode of the first single-crystalline silicon diode 18 is connected to the Al electrode 38 formed on the N-type diffusion region 35. The anode of the first single-crystalline silicon diode 18 is connected to an Al electrode (not shown) via the P+ diffusion region 40. The presence of the P+ diffusion region 40 allows formation of an ohmic contact in the P-type diffusion well region 36.

Stacking the diode circuits (polysilicon silicon diodes) and the single-crystalline silicon diodes in multiple layers in this way leads to reduction of the footprint of the protective diode structure. That is, the stacking is effective for reducing the footprint of the entire device.

Next, an operation of the protective element (diode) in the case where an ESD voltage is applied to the gate of the MOS transistor 1 of the semiconductor device 100 configured as described above will be described. Referring to FIG. 1 and focusing on the following cases (1) to (6), possible potentials at the gate, the source and the drain of the MOS transistor 1 and possible connections therebetween will be described.

In the following description, a plurality of first polysilicon diodes 16 and a plurality of second polysilicon diodes 17 are formed as shown in FIG. 1. However, the protective element operates in the same way even if a single first polysilicon diode 16 and a single second polysilicon diode 17 are formed.

In the following description, it will be assumed that the first polysilicon diodes 16 and the second polysilicon diodes 17 each have a reverse withstand voltage (reverse breakdown voltage) of about 10 V, the first diode circuit 116 includes three first polysilicon diodes 16 and thus has a total reverse withstand voltage of about 30 V, and the second diode circuit 117 includes three second polysilicon diodes 17 and thus has a total reverse withstand voltage of about 30 V. In addition, the first single-crystalline diode 18 and the second single-crystalline diode 19 formed on the semiconductor substrate each have a reverse withstand voltage (reverse breakdown voltage) of about 20 V.

Case (1): Gate is at Positive Potential, Source is Grounded, and Drain is Open

In this case, when the voltage (gate voltage) at the first terminal (gate terminal) is higher than about 22 V, for example, an ESD current flows from the first terminal 4 to the second terminal (source terminal) 6 through the first diode circuit 116 and the first single-crystalline silicon diode 18 along a discharge path 22.

The voltage of 22V mentioned above is the sum of the forward threshold voltage (about 2.1 V) of the first diode circuit 116 and the reverse withstand voltage (20 V) of the first single-crystalline silicon diode 18.

In this case, since the reverse withstand voltage of the second diode circuit 117 is 30 V, no current flows from the first terminal 4 to the second single-crystalline silicon diode 19.

Case (2): Gate is at Negative Potential, Source is Grounded, and Drain is Open

In this case, when the voltage at the first terminal 4 is lower than about −23 V, for example, an ESD current flows from the second terminal 6 to the first terminal 4 through the parasitic diode 20, the second single-crystalline silicon diode 19 and the second diode circuit 117 along discharge paths 23 and 21.

The voltage of 23V mentioned above is the sum of the forward threshold voltage (about 0.7 V) of the parasitic diode 20, the reverse withstand voltage (20 V) of the second single-crystalline silicon diode 19 and the forward threshold voltage (about 2.1 V) of the second diode circuit 117.

In this case, since the reverse withstand voltage of the first diode circuit 116 is 30 V, no current flows from the second terminal 6 to the first single-crystalline silicon diode 18.

Case (3): Gate is at Positive Potential, Drain is Grounded, and Source is Open

In this case, when the voltage at the first terminal 4 is higher than about 23 V, for example, an ESD current flows from the first terminal 4 to the third terminal (drain terminal) 7 through the first diode circuit 116, the single-crystalline silicon diode 18 and the parasitic diode 20 along the discharge paths 22 and 23.

The voltage of 23V mentioned above is the sum of the forward threshold voltage (about 2.1 V) of the first diode circuit 116, the reverse withstand voltage (20 V) of the first single-crystalline silicon diode 18 and the forward threshold voltage (about 0.7 V) of the parasitic diode 20.

In this case, since the reverse withstand voltage of the second diode circuit 117 is 30 V, no current flows from the first terminal 4 to the second single-crystalline silicon diode 19.

Case (4): Gate is at Negative Potential, Drain is Grounded, and Source is Open

In this case, when the voltage at the first terminal 4 is lower than about −22 V, for example, an ESD current flows from the third terminal 7 to the first terminal 4 through the second single-crystalline silicon diode 19 and the second diode circuit 117 along the discharge path 21.

The voltage of 22V mentioned above is the sum of the reverse withstand voltage (20 V) of the second single-crystalline silicon diode 19 and the forward threshold voltage (about 2.1 V) of the second diode circuit 117.

In this case, since the reverse withstand voltage of the first diode circuit 116 is 30 V, no current flows from the third terminal 7 to the first single-crystalline silicon diode 18.

Case (5): Gate is at Positive Potential, Source is Grounded, and Drain is Open

In this case, when the voltage at the first terminal 4 is higher than about 22 V, for example, an ESD current flows from the first terminal 4 to the second terminal 6 through the first diode circuit 116 and the first single-crystalline silicon diode 18 along the discharge path 22.

The voltage of 22V mentioned above is the sum of the forward threshold voltage (about 2.1 V) of the first diode circuit 116 and the reverse withstand voltage (20 V) of the first single-crystalline silicon diode 18.

In this case, since the reverse withstand voltage of the second diode circuit 117 is 30 V, no current flows from the first terminal 4 to the second single-crystalline silicon diode 19.

Case (6): Gate is at Negative Potential, Source is Grounded, and Drain is Open

In this case, when the voltage at the first terminal 4 is lower than about −22 V, for example, an ESD current flows from the third terminal 7 to the first terminal 4 through the second single-crystalline silicon diode 19 and the second diode circuit 117 along discharge path 21.

The voltage of 22V mentioned above is the sum of the reverse withstand voltage (20 V) of the second single-crystalline silicon diode 19 and the forward threshold voltage (about 2.1 V) of the second diode circuit 117.

In this case, since the reverse withstand voltage of the first diode circuit 116 is 30 V, no current flows from the third terminal 7 to the first single-crystalline silicon diode 18.

In all of the cases (1) to (6) described above, the first diode circuit 116 and the second diode circuit 117 in the semiconductor device 100 operate in the forward direction.

Therefore, the problem with the polysilicon diodes that the ESD resistance is low in the case of a reverse bias can be avoided.

Furthermore, the required withstand voltage of the first single-crystalline silicon diode 18 and the second single-crystalline silicon diode 19 is about 20 V, and this specification can be met on the MOS transistor structure.

Furthermore, since the MOS transistor 1 is formed on the single-crystalline silicon substrate, the ESD resistance can be adequately improved.

As described above, the semiconductor device according to this embodiment is improved in ESD resistance of the MOS transistor.

Depending on the required ESD resistance, the polysilicon diodes may be connected in parallel with each other.

Furthermore, single-crystalline silicon diodes connected in series or parallel with each other may be used. Furthermore, the same effects can be achieved even if the anode and cathode of each diode in this embodiment are symmetrically interchanged.

### Embodiment 2

In an embodiment 2, another configuration of the MOS transistor intended to improve the ESD resistance will be described.

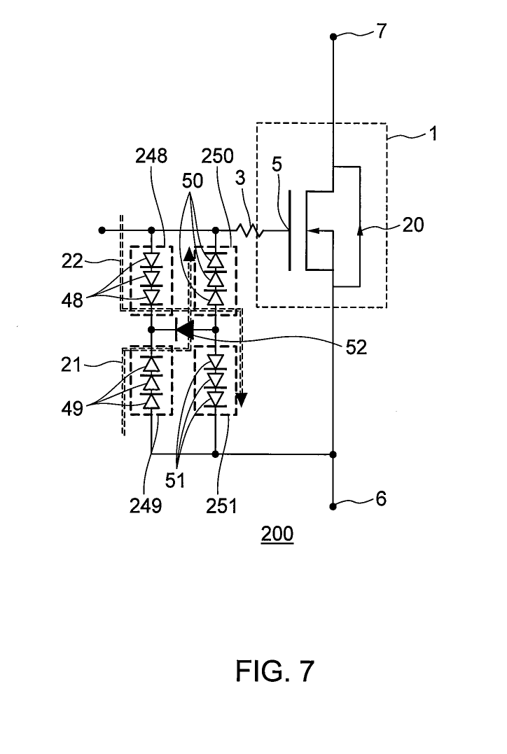

FIG. 7 is a circuit diagram showing an exemplary circuit configuration of a semiconductor device 200 according to the embodiment 2 of the present invention, which is an aspect of the present invention.

As shown in FIG. 7, the semiconductor device 200 has a MOS transistor 1, a resistor 3, a first terminal (gate terminal) 4, a second terminal (source terminal) 6, a third terminal (drain terminal) 7, a first diode circuit 248, a second diode circuit 249, a third diode circuit 250, a fourth diode circuit 251 and a single-crystalline silicon diode 52.

The MOS transistor 1, the resistor 3, the first terminal (Gate terminal) 4, the second terminal (source terminal) 6 and the third terminal (Drain terminal) 7 of the semiconductor device 200 are the same as those of the first semiconductor device 100 according to the embodiment 1.

The first diode circuit 248 is formed on a semiconductor substrate with an insulating film interposed therebetween. The first diode circuit 248 is composed of a plurality of first polysilicon diodes 48 made of polysilicon connected in series with each other. The first diode circuit 248 is connected to the first terminal 4 at the anode side of the first polysilicon diodes 48.

Alternatively, the first diode circuit 248 may be composed of a single first polysilicon diode 48. In that case, the first polysilicon diode 48 is formed on the semiconductor substrate with an insulating film interposed therebetween and is made of polysilicon. The first polysilicon diode 48 is connected to the first terminal 4 at the anode thereof.

The second diode circuit 249 is formed on the semiconductor substrate with an insulating film interposed therebetween. The second diode circuit 249 is composed of a plurality of second polysilicon diodes 49 made of polysilicon connected in series with each other. The second diode circuit 249 is connected to the cathode side of the first diode circuit 248 at the cathode side thereof and to the second terminal 6 at the anode side thereof.

Alternatively, the second diode circuit 249 may be composed of a single second polysilicon diode 49. In that case, the second polysilicon diode 49 is formed on the semiconductor substrate with an insulating film interposed therebetween and is made of polysilicon. The second polysilicon diode 49 is connected to the cathode side of the first diode circuit 248 at the cathode thereof and to the second terminal 6 at the anode thereof.

The third diode circuit 250 is formed on the semiconductor substrate with an insulating film interposed therebetween. The third diode circuit 250 is composed of a plurality of third polysilicon diodes 50 made of polysilicon connected in series with each other. The third diode circuit 250 is connected to the first terminal 4 at the cathode side of the third polysilicon diodes 50.

Alternatively, the third diode circuit 250 may be composed of a single third polysilicon diode 50. In that case, the third polysilicon diode 50 is formed on the semiconductor substrate with an insulating film interposed therebetween and is made of polysilicon. The third polysilicon diode 50 is connected to the third terminal 4 at the cathode thereof.

The fourth diode circuit 251 is formed on the semiconductor substrate with an insulating film interposed therebetween. The fourth diode circuit 251 is composed of a plurality of fourth polysilicon diodes 51 made of polysilicon connected in series with each other. The fourth diode circuit 251 is connected to the anode side of the third diode circuit 250 at the anode side thereof and to the anode side of the second diode circuit 249 at the cathode side thereof.

Alternatively, the fourth diode circuit 251 may be composed of a single fourth polysilicon diode 51. In that case, the fourth polysilicon diode 51 is formed on the semiconductor substrate with an insulating film interposed therebetween and is made of polysilicon. The fourth polysilicon diode 51 is connected to the anode side of the third diode circuit 250 at the anode thereof and to the anode side of the second diode circuit 249 at the cathode thereof.

The single-crystalline silicon diode 52 is made of single-crystalline silicon. The single-crystalline silicon diode 52 is connected to the cathode side of the first diode circuit 248 at the cathode thereof and to the anode side of the third diode circuit 250 at the anode thereof.

The single-crystalline silicon diode 52 has a reverse breakdown voltage lower than the sum of the reverse breakdown voltages of the plurality of polysilicon diodes of the first diode circuit 248 connected in series with each other. In addition, the single-crystalline silicon diode 52 has a reverse breakdown voltage lower than the sum of the reverse breakdown voltages of the plurality of polysilicon diodes of the second diode circuit 249 connected in series with each other. In addition, the single-crystalline silicon diode 52 has a reverse breakdown voltage lower than the sum of the reverse breakdown voltages of the plurality of polysilicon diodes of the third diode circuit 250 connected in series with each other. In addition, the single-crystalline silicon diode 52 has a reverse breakdown voltage lower than the sum of the reverse breakdown voltages of the plurality of polysilicon diodes of the fourth diode circuit 251 connected in series with each other.

In the case where the first to fourth diode circuits 248, 249, 250 and 251 are composed of single first to fourth polysilicon diodes 48, 49, 50 and 51, respectively, the single-crystalline silicon diode 52 is connected to the cathode of the first polysilicon diode 48 at the cathode thereof and to the anode of the third polysilicon diode 50 at the anode thereof. In that case, the single-crystalline silicon diode 52 has a reverse breakdown voltage lower than the reverse breakdown voltage of the first to fourth polysilicon diodes 48, 49, 50 and 51.

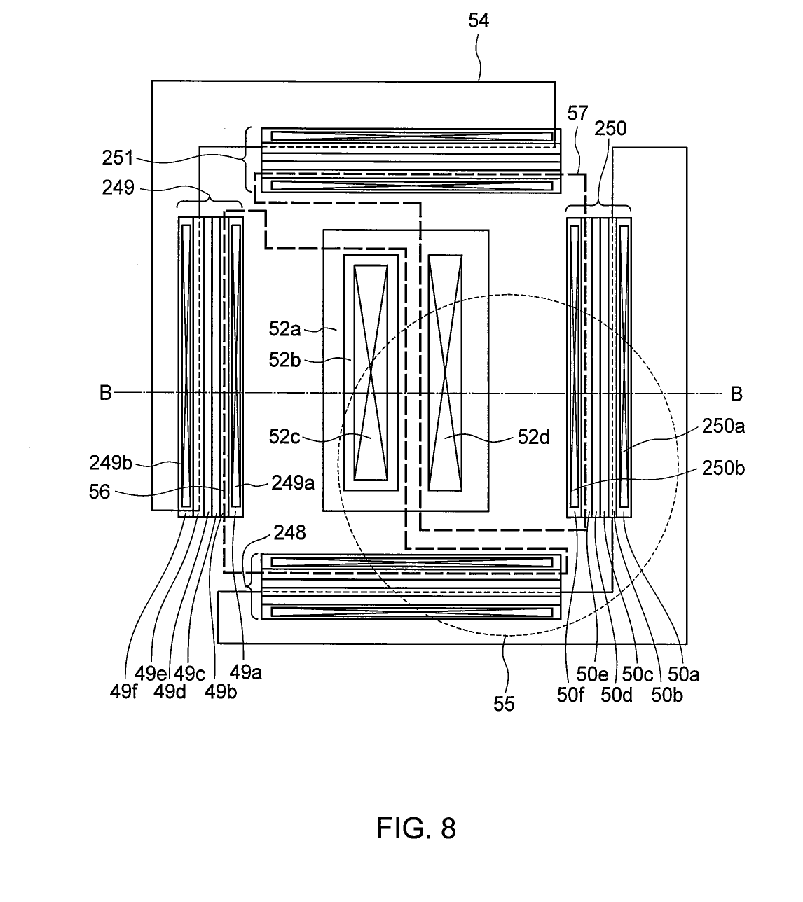

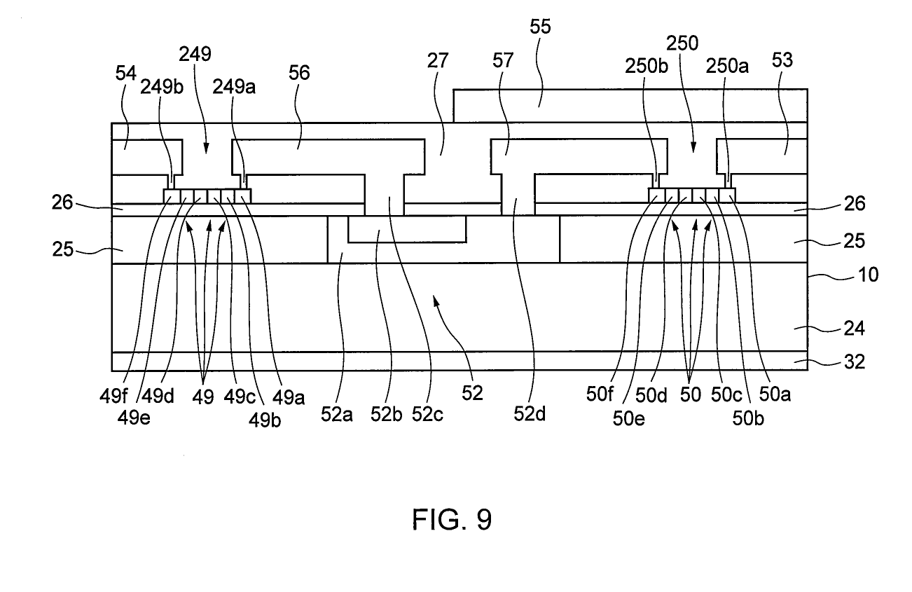

FIG. 8 is a plan view showing an exemplary layout of a protective diode structure of the semiconductor device 200 shown in FIG. 7. FIG. 9 is a cross-sectional view of the semiconductor device 200 taken along the line B-B in FIG. 8. For the sake of clarity, these drawings show only essential parts. FIG. 9 shows a cross section of the single-crystalline silicon diode 52 and the vicinity thereof. In FIGS. 8 and 9, the parts denoted by the same reference numerals as those in the drawings showing the embodiment 1 are the same parts as those in the embodiment 1.

As shown in FIGS. 8 and 9, the second diode circuit 249 is formed on a semiconductor substrate 10 with an insulating film 26 interposed therebetween. Al electrodes 249a and 249b are formed on the opposite ends of the second diode circuit 249. Similarly, the third diode circuit 250 is formed on the semiconductor substrate 10 with the insulating film 26 interposed therebetween. Al electrodes 250a and 250b are formed on the opposite ends of the third diode circuit 250.

The second polysilicon diodes (PN-junction diodes) 49 connected in series with each other are composed of P-type polysilicon layers 49b, 49d and 49f formed on the insulating film 26 and N-type polysilicon layers 49a, 49c and 49e formed on the insulating film 26. Similarly, the third polysilicon diodes (PN-junction diodes) 50 connected in series with each other are composed of P-type polysilicon layers 50b, 50d and 50f formed on the insulating film 26 and N-type polysilicon layers 50a, 50c and 50e formed on the insulating film 26.

The first and fourth diode circuits 248 and 251 have the same cross-sectional structure as that described above.

The single-crystalline silicon diode (PN-junction diode) 52 is composed of a P-type diffusion well region 52a formed in an N-type epitaxial layer 25 and an N-type diffusion region 52b formed in the P-type diffusion well region 52a.

The cathode of the single-crystalline silicon diode 52 is connected to an electrode 52c formed on the N-type diffusion region 52b. The anode of the single-crystalline silicon diode 52 is connected to an electrode 52d. A P+ diffusion region (not shown) for forming an ohmic contact to the electrode 52d may be formed in the P-type diffusion well region 52a.

A gate line 53 connected to the first terminal 4 is connected to an electrode 250a. A source line 54 is connected to an electrode 249b.

A gate pad electrode 55 is formed over the single-crystalline silicon diode 52, the first diode circuit 248 and the third diode circuit 250 with an interlayer insulating film 27 interposed therebetween.

An electrode 56 connects the electrode (cathode) 52c of the single-crystalline diode 52 and the cathode side of the first diode circuit 248 and the second diode circuit 249 to each other.

An electrode 57 connects the electrode (anode) 52d of the single-crystalline diode 52 and the cathode side of the third diode circuit 250 and the fourth diode circuit 251 to each other.

These electrodes are electrically isolated from each other by the interlayer insulating film 27.

As in the embodiment 1, the polysilicon diodes can be connected in series with each other by metal electrodes. In that case, no NPN structure is formed, so that the snap-back effect can be suppressed. As a result, a desired sufficiently high withstand voltage can be assured.

The same effect can be achieved even if, as an alternative to the metal electrodes, semiconductor parts having a minority carrier recombination rate approximately equal to that of the metal electrodes are connected between the polysilicon diodes connected in series with each other.

Next, an operation of the protective element (diode) in the case where an ESD voltage is applied between the gate and the source of the MOS transistor 1 of the semiconductor device 200 configured as described above will be described.

As described above, the reverse withstand voltage (reverse breakdown voltage) of the second diode circuit 249 and the third diode circuit 250 is set to be higher than the reverse withstand voltage of the single-crystalline silicon diode 52.

Therefore, when the potential at the first terminal (gate terminal) is positive with respect to the second terminal (source terminal) 6, an ESD current flows from the first terminal 4 to the second terminal 6 along a current path 22. Therefore, the MOS transistor 1 can be protected.

In addition, as described above, the reverse withstand voltage of the first diode circuit 248 and the fourth diode circuit 251 is set to be higher than the reverse withstand voltage of the single-crystalline silicon diode 52.

Therefore, when the potential at the first terminal 4 is negative with respect to the second terminal 6, an ESD current flows from the second terminal 6 to the first terminal 4 along a current path 21. Therefore, the MOS transistor 1 can be protected.

According to this embodiment, a single single-crystalline silicon diode 52 suffices for protection, so that the footprint of the device can be effectively reduced.

In the above description of the embodiment 2, the second diode circuit 249 is connected to the second terminal 6 at the anode side thereof, and the fourth diode circuit 251 is connected to the second terminal 6 at the cathode side.

However, the same effects and advantages can be achieved even if the second diode circuit 249 is connected to the third terminal 7 at the anode side, and the fourth diode circuit 251 is connected to the third terminal 7 at the cathode side

As described above, the semiconductor device according to this embodiment is improved in ESD resistance of the MOS transistor.

What is claimed is:

1. A semiconductor device, comprising:
a MOS transistor that is formed on a semiconductor substrate, and has a gate connected to a first terminal, a source connected to a second terminal and a drain connected to a third terminal;
a first polysilicon diode that is formed on the semiconductor substrate with an insulating film interposed therebetween, has an anode connected to the first terminal, and is made of polysilicon;
a first single-crystalline silicon diode that has a cathode connected to a cathode of the first polysilicon diode and an anode connected to the second terminal, has a reverse breakdown voltage lower than a reverse breakdown voltage of the first polysilicon diode, and is made of single-crystalline silicon;
a second polysilicon diode that is formed on the semiconductor substrate with an insulating film interposed therebetween, has a cathode connected to the first terminal, and is made of polysilicon; and
a second single-crystalline silicon diode that has an anode connected to an anode of the second polysilicon diode and a cathode connected to the third terminal, has a reverse breakdown voltage lower than a reverse breakdown voltage of the second polysilicon, and is made of single-crystalline silicon.

2. The semiconductor device according to claim 1, further comprising a resistor that is connected between the first terminal and the gate of the MOS transistor.

3. The semiconductor device according to claim 1, wherein the first single-crystalline silicon diode and the second single-crystalline silicon diode are formed in a single-crystalline silicon layer in the semiconductor substrate.

4. A semiconductor device, comprising:
a MOS transistor that is formed on a semiconductor substrate, and has a gate connected to a first terminal, a source connected to a second terminal and a drain connected to a third terminal;
a first diode circuit that is formed on the semiconductor substrate with an insulating film interposed therebetween, includes a plurality of polysilicon diodes made of polysilicon connected in series with each other, and is connected to the first terminal at an anode side thereof;
a first single-crystalline silicon diode that is connected to a cathode side of the first diode circuit at a cathode thereof and to the second terminal at an anode thereof, has a reverse breakdown voltage lower than a sum of reverse breakdown voltages of the plurality of polysilicon diodes of the first diode circuit, and is made of single-crystalline silicon;
a second diode circuit that is formed on the semiconductor substrate with an insulating film interposed therebetween, includes a plurality of polysilicon diodes made of polysilicon connected in series with each other, and is connected to the first terminal at a cathode side thereof; and
a second single-crystalline silicon diode that is connected to an anode side of the second diode circuit at an anode thereof and to the third terminal at a cathode thereof, has a reverse breakdown voltage lower than a sum of reverse breakdown voltages of the plurality of polysilicon diodes of the second diode circuit connected in series with each other, and is made of single-crystalline silicon.

5. The semiconductor device according to claim 4, further comprising a metal part that is connected between the first polysilicon diodes connected in series with each other.

6. The semiconductor device according to claim 4, further comprising a resistor that is connected between the first terminal and the gate of the MOS transistor.

7. The semiconductor device according to claim 4, wherein the first single-crystalline silicon diode and the second single-crystalline silicon diode are formed in a single-crystalline silicon layer in the semiconductor substrate.

8. A semiconductor device, comprising:
a MOS transistor that is formed on a semiconductor substrate and has a gate connected to a first terminal, a source connected to a second terminal and a drain connected to a third terminal;
a first polysilicon diode that is formed on the semiconductor substrate with an insulating film interposed therebetween, has an anode connected to the first terminal, and is made of polysilicon;
a second polysilicon diode that is formed on the semiconductor substrate with an insulating film interposed therebetween, has a cathode connected to a cathode of the first polysilicon diode and an anode connected to the second or third terminal, and is made of polysilicon;
a third polysilicon diode that is formed on the semiconductor substrate with an insulating film interposed therebetween, has a cathode connected to the first terminal, and is made of polysilicon;
a fourth polysilicon diode that is formed on the semiconductor substrate with an insulating film interposed therebetween, has an anode side connected to an anode of the third polysilicon diode and a cathode connected to the anode of the second polysilicon diode, and is made of polysilicon; and
a single-crystalline silicon diode that has a cathode connected to the cathode of the first polysilicon diode and an anode connected to the anode of the third polysilicon diode, has a reverse breakdown voltage lower than a reverse breakdown voltage of the first polysilicon diode, a reverse breakdown voltage of the second polysilicon diode, a reverse breakdown voltage of the third polysilicon diode and a reverse breakdown voltage of the fourth polysilicon diode, and is made of single-crystalline silicon.

9. The semiconductor device according to claim 8, further comprising a resistor that is connected between the first terminal and the gate of the MOS transistor.

10. The semiconductor device according to claim 8, wherein the ingle-crystalline silicon diode is formed in a single-crystalline silicon layer in the semiconductor substrate.

11. A semiconductor device, comprising:
a MOS transistor that is formed on a semiconductor substrate and has a gate connected to a first terminal, a source connected to a second terminal and a drain connected to a third terminal;
a first diode circuit that is formed on the semiconductor substrate with an insulating film interposed therebetween, includes a plurality of polysilicon diodes made of polysilicon connected in series with each other and is connected to the first terminal at an anode side thereof;
a second diode circuit that is formed on the semiconductor substrate with an insulating film interposed therebetween, includes a plurality of polysilicon diodes made of polysilicon connected in series with each other and is connected to a cathode side of the first diode circuit at a cathode side thereof and to the second or third terminal at an anode side thereof;
a third diode circuit that is formed on the semiconductor substrate with an insulating film interposed therebetween, includes a plurality of polysilicon diodes made of polysilicon connected in series with each other and is connected to the first terminal at a cathode side thereof;
a fourth diode circuit that is formed on the semiconductor substrate with an insulating film interposed therebetween, includes a plurality of polysilicon diodes made of polysilicon connected in series with each other and is connected to an anode side of the third diode circuit at an anode side thereof and to the anode side of the second diode circuit at a cathode side thereof; and
a single-crystalline silicon diode that is connected to the cathode side of the first diode circuit at a cathode thereof and to the anode side of the third diode circuit at an anode thereof, has a reverse breakdown voltage lower than a sum of reverse breakdown voltages of the plurality of polysilicon diodes of the first diode circuit, a sum of reverse breakdown voltages of the plurality of polysilicon diodes of the second diode circuit, a sum of reverse breakdown voltages of the plurality of polysilicon diodes of the third diode circuit and a sum of reverse breakdown voltages of the plurality of polysilicon diodes of the fourth diode circuit, and is made of single-crystalline silicon.

12. The semiconductor device according to claim 11, further comprising a metal part that is connected between the polysilicon diodes connected in series with each other.

13. The semiconductor device according to claim 11, further comprising a resistor that is connected between the first terminal and the gate of the MOS transistor.

14. The semiconductor device according to claim 11, wherein the single-crystalline silicon diode is formed in a single-crystalline silicon layer in the semiconductor substrate.
